(19) United States
(12) Patent Application Publication
(10) Pub. No.: US 2021/0202231 A1
(43) Pub. Date: Jul. 1, 2021

(54) Systems and Methods for Removal of Hardmask

(71) Applicants: Mattson Technology, Inc., Fremont, CA (US); Beijing E-Town Semiconductor Technology, Co., LTD, Beijing (CN)

(72) Inventors: Jeyta Anand Sahay, Livermore, CA (US); Hua Chung, Saratoga, CA (US); Qi Zhang, San Jose, CA (US)

(21) Appl. No.: 17/120,382

(22) Filed: Dec. 14, 2020

Related U.S. Application Data
(60) Provisional application No. 62/955,518, filed on Dec. 31, 2019.

(51) Int. Cl. H01L 21/02; H01L 21/311; B08B 7/00; B08B 7/04

(52) U.S. Cl. CPC H01L 21/0206; H01L 21/0223; B08B 7/04; B08B 7/0035; H01L 21/31144

(57) ABSTRACT

Apparatus, systems, and methods for conducting a hardmask (e.g., boron doped amorphous carbon hardmask) removal process on a workpiece are provided. In one example implementation, a method includes supporting a workpiece on a workpiece support in a processing chamber. The method can include generating a plasma from a process gas in a plasma chamber using a plasma source. The process gas includes a fluorine containing gas. The method can include exposing the workpiece to one or more radicals generated in the plasma to perform a plasma strip process on the workpiece to at least partially remove the hardmask layer from the workpiece. The method can include exposing the workpiece to one or more hydrogen radicals as a passivation agent during the plasma strip process.

### PRIORITY CLAIM

The present application claims the benefit of priority of U.S. Provisional Application Ser. No. 62/955,518, filed on Dec. 31, 2019, titled “Systems and Methods for Removal of Hardmask,” which is incorporated herein by reference.

### FIELD

The present disclosure relates generally to processing semiconductor workpieces.

### BACKGROUND

Plasma strip processes (e.g., dry strip processes) can be used in semiconductor fabrication as a method for removing hardmask and/or other materials patterned on a workpiece. Plasma strip processes can use reactive species (e.g., radicals) extracted from a plasma generated from one or more process gases to etch and/or remove photoresist and other mask layers from a surface of a workpiece. For instance, in some plasma strip processes, neutral species from a plasma generated in a remote plasma chamber pass through a separation grid into a processing chamber. The neutral species can be exposed to a workpiece, such as a semiconductor wafer, to remove hardmask from the surface of the workpiece.

### SUMMARY

Aspects and advantages of embodiments of the present disclosure will be set forth in part in the following description, or may be learned from the description, or may be learned through practice of the embodiments.

In one example implementation, a method includes supporting a workpiece on a workpiece support in a processing chamber. The method can include generating a plasma from a process gas in a plasma chamber using a plasma source. The process gas includes a fluorine containing gas. The method can include exposing the workpiece to one or more radicals generated in the plasma to perform a plasma strip process on the workpiece to at least partially remove the hardmask layer from the workpiece. The method can include exposing the workpiece to one or more hydrogen radicals as a passivation agent during the plasma strip process.

Other example aspects of the present disclosure are directed to systems, methods, and apparatus for processing of workpieces.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example hardmask removal process on a high aspect ratio structure;

FIG. 2 depicts an example hardmask removal process on a high aspect ratio structure according to example embodiments of the present disclosure;

FIG. 3 depicts an example plasma processing apparatus according to example embodiments of the present disclosure;

FIG. 4 depicts an example plasma processing apparatus according to example embodiments of the present disclosure;

FIG. 5 depicts a flow diagram of an example method according to example embodiments of the present disclosure;

FIG. 6 depicts an example plasma processing apparatus according to example embodiments of the present disclosure;

FIG. 7 depicts example injection of water vapor at a separation grid according to example embodiments of the present disclosure;

FIG. 8 depicts a flow diagram of an example method according to example embodiments of the present disclosure;

FIG. 9 depicts an example plasma processing apparatus according to example embodiments of the present disclosure; and

FIG. 10 depicts an example plasma processing apparatus according to example embodiments of the present disclosure;

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to processes for removing a hardmask layer (e.g., boron doped amorphous carbon hardmask (BACL)) from a workpiece in semiconductor processing. Various materials such as boron or metal doped amorphous carbon can be used as a hardmask layer in high aspect ratio dielectric etch applications to produce advanced semiconductor devices. Plasma strip processes can be used to remove remaining hardmask after conducting etch processes. As device features continuously shrink, very high selectivity of hardmask relative to silicon dioxide and silicon nitride layers can be required for post etch hardmask removal, particularly in high aspect ratio structures, such as vertical NAND structures.

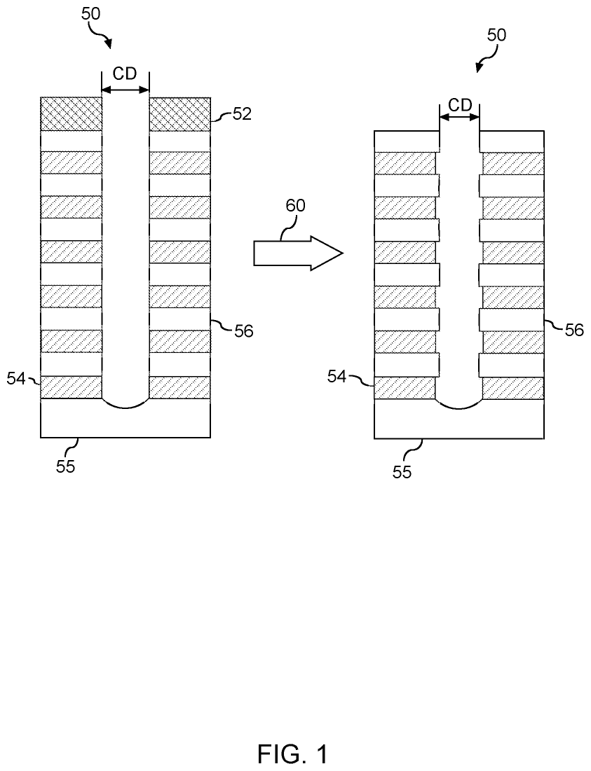

Inadequate selectivity of the hardmask relative to silicon dioxide and silicon nitride in plasma strip processes can pose challenges in workpiece processing, such as hardmask removal from high aspect ratio structures in semiconductor processing. For example, FIG. 1 depicts an example hardmask removal process for a high aspect ratio structure 50. The high aspect ratio structure 50 includes a plurality of silicon nitride layers 54 and silicon dioxide layers 56 disposed on a substrate 55, such as a silicon substrate. The high aspect ratio structure 50 is associated with a critical dimension CD. A hardmask 52 can remain on the high aspect ratio structure 50 after an etch process.

A plasma strip process 60 can be conducted on the high aspect ratio structure 50 to remove the hardmask 52. The plasma strip process can expose the hardmask 52 to one or more species (e.g., halogen species) generated in a plasma chamber to remove the hardmask 52. As shown in FIG. 1, if selectivity of the plasma strip process for the hardmask 52 is poor relative to silicon nitride and silicon dioxide, the high aspect ratio structure 50 can result in a saw-toothed sidewall, negatively affecting the critical dimension CD requirements.

Example aspects of the present disclosure are directed to a plasma strip process with improved selectivity and faster ash rate for removal of a hardmask layer, such as removal of a hardmask layer from a high aspect ratio structure having one or more silicon nitride layers and one or more silicon dioxide layers. In some embodiments, one or more hydrogen radicals can be used in conjunction with a fluorine containing chemistry as a process gas during the plasma strip process. The one or more hydrogen radicals (e.g., neutral hydrogen radicals) can act as passivating agents to reduce silicon dioxide and silicon nitride removal during the strip process.

The hydrogen radicals can be exposed to the workpiece in various ways without deviating from the scope of the present disclosure. For instance, in some embodiments, the process gas can include an HF gas (e.g., HF vapor). The process gas can include other gases, including one or more of fluorine containing gases and other gases (e.g., oxygen gas, hydrogen gas, dilution gas, etc.). A plasma source (e.g., inductive plasma source) can induce a plasma in the process gas to generate etchant species (e.g., fluorine radicals) and passivation species (e.g., hydrogen radicals). The HF gas can be generated directly into the plasma chamber from an HF source. In addition and/or in the alternative, hydrogen and fluorine species can be generated in the plasma from a process gas containing a mixture of a hydrogen containing gas and a fluorine containing gas. As another example, an HF gas can be delivered post plasma to a processing chamber below a separation grid separating a plasma chamber from the processing chamber. As yet another example, the HF gas can be introduced post plasma at the separation grid, such as between grid plates of the separation grid.

In this way, hydrogen radicals generated from dissociation of HF gas can passivate the surface of the oxide and nitride layers in a high aspect ratio structure and prevent its removal by the fluorine radicles. The hard mask layer (e.g., BACL hardmask) can be removed by the fluorine radicals.

In some embodiments, an oxidation step can be performed to oxidize the hardmask layer prior to exposing the workpiece to hydrogen radicals and fluorine radicals for removal of the hard mask layer. For instance, an oxygen containing gas can be used in the process gas in a first part of the process. The HF gas can be used in the process gas as a second part of the process. In the first part of the process, the oxygen containing gas can oxidize and remove carbonaceous material from a BACL layer while also oxidizing boron to boron oxide. In the second part of the process, the HF gas can dissociate to fluorine radicals and hydrogen radicals. The fluorine radicals can remove the boron oxide while the hydrogen radicals can passivate the oxide and nitride layers in the high aspect ratio structure to reduce removal of these layers by the fluorine radicals. In some embodiments, the first part of the process and the second part of the process can be performed in a cyclic manner.

The hardmask removal processes according to example aspects of the present disclosure can provide a number of technical effects and benefits. For example, the hardmask removal processes according to example aspects of the present disclosure can provide for improved selectivity of the hardmask layer relative to silicon dioxide layers and silicon nitride layers in a workpiece. As another example, the hardmask removal processes according to example aspects of the present disclosure can provide a high ash rate, such as greater than about 1500 Angstroms per minute.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within twenty percent (20%) of the stated numerical value. A “pedestal” refers to any structure that can be used to support a workpiece.

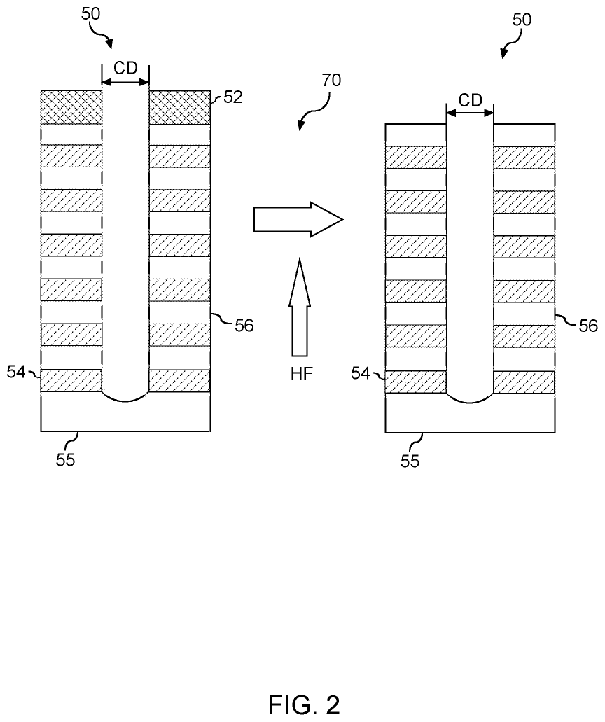

FIG. 2 depicts an overview of an example hardmask removal process 70 for a workpiece having a high aspect ratio structure 50 according to example embodiments of the present disclosure. The high aspect ratio structure 50 includes a plurality of silicon nitride layers 54 and a plurality of silicon dioxide layers 56 disposed on a substrate 55, such as a silicon substrate. The high aspect ratio structure 50 is associated with a critical dimension CD. A hardmask 52 can remain on the high aspect ratio structure 50 after an etch process.

A plasma strip process 70 according to example aspects of the present disclosure can be conducted on the high aspect ratio structure 50 to remove the hardmask 52. The plasma strip process 70 can expose the hardmask 52 to one or more fluorine species generated in a plasma chamber from a fluorine containing gas (e.g., HF) to remove the hardmask 52. The plasma strip process 70 can expose the workpiece to one or more hydrogen radicals as a passivation agent for the silicon nitride and silicon dioxide layers.

Passivation of the silicon nitride and silicon dioxide layers leads to improved selectivity of the plasma strip process 70 for a hardmask layer (e.g., boron doped amorphous hardmask layer) relative to the silicon nitride and silicon dioxide layers. Because of the improved selectivity of the plasma strip process 70, the high aspect ratio structure 50 can result in a smooth sidewall, leading to improved critical dimension (CD) control.

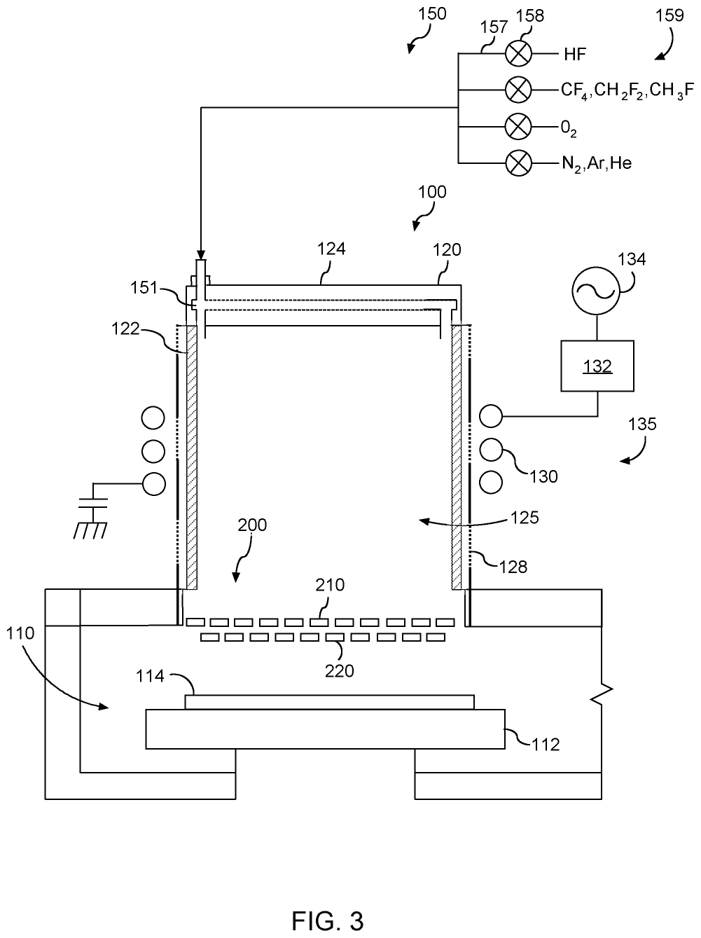

FIG. 3 depicts an example plasma processing apparatus 100 that can be used to perform hardmask removal processes according to example embodiments of the present disclosure. As illustrated, plasma processing apparatus 100 includes a processing chamber 110 and a plasma chamber 120 that is separated from the processing chamber 110. Processing chamber 110 includes a workpiece support or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of workpiece 114 through a separation grid assembly 200.

Aspects of the present disclosure are discussed with reference to an inductively coupled plasma source for purposes of illustration and discussion. Those of ordinary skill in the art, using the disclosures provided herein, will understand that any plasma source (e.g., inductively coupled plasma source, capacitively coupled plasma source, etc.) can be used without deviating from the scope of the present disclosure.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases (e.g., as described in detail below) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 3, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded. In some embodiments, the grid assembly can include a single grid with a single grid plate.

As shown in FIG. 3, the apparatus 100 can include a gas delivery system 150 configured to deliver process gas to the plasma chamber 120, for instance, via gas distribution channel 151 or other distribution system (e.g., showerhead). The gas delivery system can include a plurality of feed gas lines 159. The feed gas lines 159 can be controlled using valves and/or mass flow controllers to deliver a desired amount of gases into the plasma chamber as process gas. As shown in FIG. 3, the gas delivery system 150 can include feed gas line(s) for delivery of an HF gas (e.g., HF vapor). The gas delivery system 150 can optionally include feed gas line(s) for delivery of other gases, such as fluorine containing gas (e.g., CF₄, CH₂F₂, CH₃F). oxygen containing gas (e.g., O₂, H₂O vapor or gas, ozone gas, N₂O, etc.), a dilution gas (e.g., N₂, Ar, He, or other inert gas).

According to example aspects of the present disclosure, the HF gas can be dissociated in the plasma chamber to generate hydrogen radicals and fluorine radicals. Neutral hydrogen radicals and neutral fluorine radicals can pass through the separation grid assembly 200 for exposure to the workpiece 114. The fluorine radicals can etch or remove a BACL hardmask or other hardmask layer on the workpiece 114. The hydrogen radicals can passivate oxide layers and/or nitride layers on the workpiece 114 during removal of the BACL hardmask or other hardmask layer on the workpiece 114.

In some embodiments, as will be discussed in detail below, an oxygen containing gas can be provided to the plasma chamber and/or the processing chamber (e.g., through the separation grid assembly 200). The oxygen containing gas can be used to oxidize a hardmask layer (e.g. BACL hardmask layer) prior to removal of the hardmask layer using fluorine radicals with hydrogen radicals as a passivation agent.

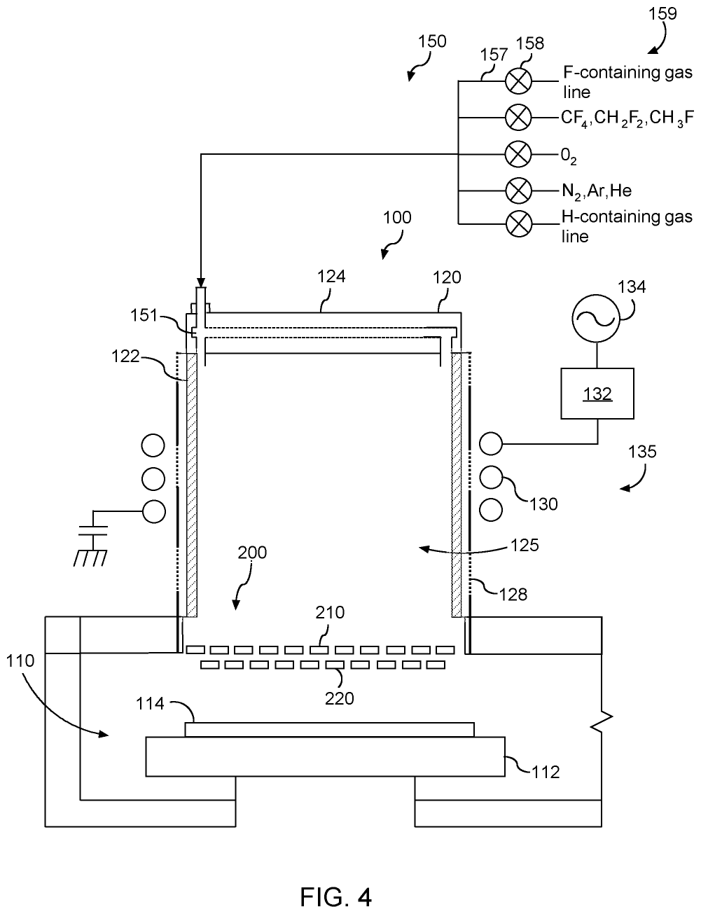

FIG. 4 depicts a plasma processing apparatus 100 that is similar to the plasma processing apparatus 100 depicted in FIG. 3. However, the gas delivery system 150 does not include feed gas line(s) that deliver HF gas (e.g., HF vapor) from a HF source (e.g., HF bottle). Rather, the gas delivery system 150 includes feed gas line(s) that deliver a fluorine containing gas (e.g., CF₄, NF₃, CH₂F₂, CH₃F, CFₓH_{y}, etc.) and feed gas line(s) that deliver a hydrogen containing gas (e.g., H₂, CH₄, C₂H₈, etc.). Hydrogen and fluorine radicals can be generated using the plasma source 135 for exposure to the workpiece during a hardmask removal process according to example embodiments of the present disclosure.

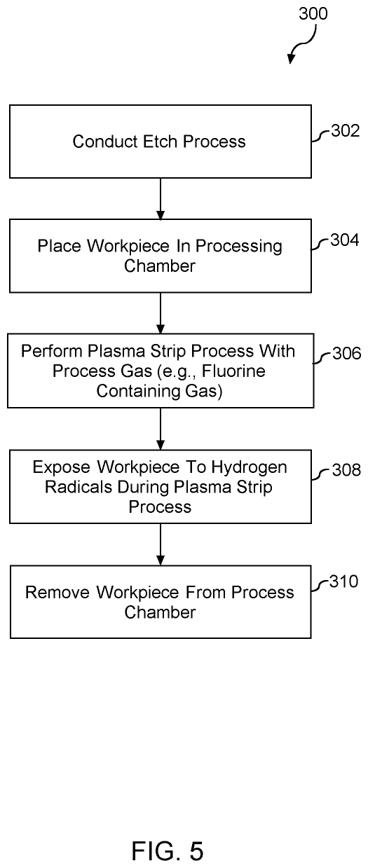

FIG. 5 depicts a flow diagram of one example method (300) according to example aspects of the present disclosure. The method (300) will be discussed with reference to the plasma processing apparatus 100 of FIG. 3 by way of example. The method (300) can be implemented in any suitable plasma processing apparatus. FIG. 5 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (302), the method can include conducting an etch process to etch a layer on a workpiece. The etch process can be carried out in a separate processing apparatus relative to the remainder of method (300) or can be conducted using the same processing apparatus. The etch process can remove at least a portion of a layer on the workpiece.

At (304), the method can include placing a workpiece in a processing chamber of a plasma processing apparatus. The processing chamber can be separated from a plasma chamber (e.g., separated by a separation grid assembly). For instance, the method can include placing a workpiece 114 onto workpiece support 112 in the processing chamber 110 of FIG. 3. The workpiece can include a BACL hardmask or other hardmask layer. The workpiece can include oxide layers and nitride layers (e.g., alternating oxide layers and nitride layers) as part of a high aspect ratio structure.

At (306), the method can include performing a plasma strip process, for instance, to remove a hardmask layer (e.g., BACL hardmask) from the workpiece. The plasma strip process can include, for instance, generating a plasma from a process gas in the plasma chamber 120, filtering ions with the separation grid assembly 200, and allowing neutral radicals to pass through the separation grid assembly 200. The neutral radicals can be exposed to the workpiece 114 to at least partially remove hardmask from the workpiece.

The process gas used during the plasma strip process at (306) can include a fluorine containing gas. For instance, the process gas can include HF (e.g., HF vapor). Other fluorine containing gases can be used without deviating from the scope of the present disclosure. In addition and/or in the alternative, the process gas can include a mixture of a fluorine containing gas (e.g., CF₄, NF₃, CH₂F₂, CH₃F, CFₓH_{y}, etc.) and a hydrogen containing gas (e.g., H₂, CH₄, C₂H₈, etc.).

Other suitable gases can be included in the process gas. For instance, the process gas can include an oxygen containing gas. The process gas can include a dilution gas, such as nitrogen gas N₂ and/or an inert gas, such as He, Ar or other inert gas. The process gas can include other fluorine containing gases (e.g., e.g., CF₄, NF₃, CH₂F₂, CH₃F, CFₓH_{y}, etc.).

At (308), the method can include exposing the workpiece to hydrogen radicals as a passivation agent. The hydrogen radicals can be generated by dissociating HF gas in the plasma chamber. The hydrogen radicals can be generated by dissociating a hydrogen containing gas provided as part of a process gas including a mixture of a fluorine containing gas and a hydrogen containing gas. The hydrogen radicals can improve selectivity of the strip processes for the hardmask layer relative to the nitride layers and oxide layers by acting as a passivation agent. Other suitable methods for introducing the hydrogen radicals as a passivation agent will be discussed in detail below.

At (310) of FIG. 5, the method can include removing the workpiece from the processing chamber. For instance, the workpiece 114 can be removed from workpiece support 112 in the processing chamber 110. The plasma processing apparatus can then be conditioned for future processing of additional workpieces.

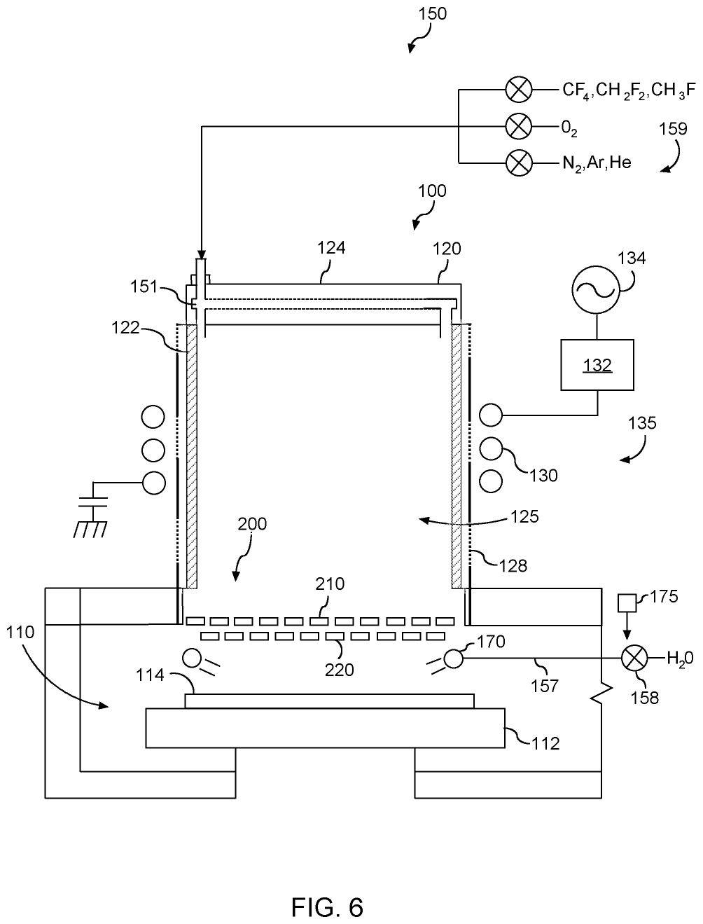

Other suitable methods for introducing hydrogen radicals as a passivation agent can be used without deviating from the scope of the present disclosure. For instance, FIG. 6 depicts a plasma processing apparatus 100 similar to that of FIG. 3. However, the apparatus 100 of FIG. 5 includes an HF gas (e.g., HF vapor) feed line 157 arranged to deliver HF into the processing chamber 110. More particularly, the HF gas feed line 157 can be coupled to HF distribution port 170 arranged to provide HF into the processing chamber 110 at a location below the separation grid 200, such as at a location between the separation grid 200 and the workpiece 114. The control valve and/or mass flow controller 158 can control the flow rate of the HF gas into the processing chamber.

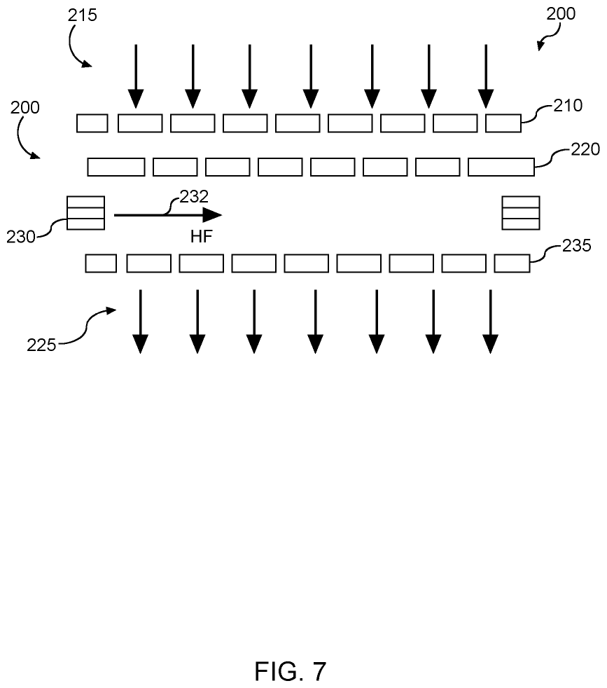

FIG. 7 depicts example introduction of HF gas into a plasma processing apparatus according to example embodiments of the present disclosure. As shown, FIG. 7 depicts an example separation grid 200 for injection of HF gas post plasma according to example embodiments of the present disclosure. The separation grid 200 includes a first grid plate 210 and a second grid plate 220 disposed in parallel relationship. The first grid plate 210 and the second grid plate 220 can provide for ion/UV filtering.

The first grid plate 210 can have a first grid pattern having a plurality of holes. The second grid plate 220 can have a second grid pattern having a plurality of holes. The first grid pattern can be the same as or different from the second grid pattern. Species 215 from the plasma can be exposed to the separation grid 200. Charged particles (e.g., ions) can recombine on the walls in their path through the holes of each grid plate 210, 220 in the separation grid 200. Neutral species can flow relatively freely through the holes in the first grid plate 210 and the second grid plate 220.

Subsequent to the second grid plate 220, an HF gas injection source 230 can be configured to introduce HF gas 232 (e.g., HF vapor) into the species passing through the separation grid 200. A mixture 225 including hydrogen radicals resulting from the injection of HF gas can pass through a third grid plate 235 for exposure to the workpiece in the processing chamber.

The present example is discussed with reference to a separation grid with three grid plates for example purposes. Those of ordinary skill in the art, using the disclosures provided herein, will understand that more or fewer grid plates can be used without deviating from the scope of the present disclosure. In addition, the HF gas can be mixed with the species at any point in the separation grid and/or after the separation grid in the processing chamber. For instance, the HF gas injection source 230 can be located between first grid plate 210 and second grid plate 220.

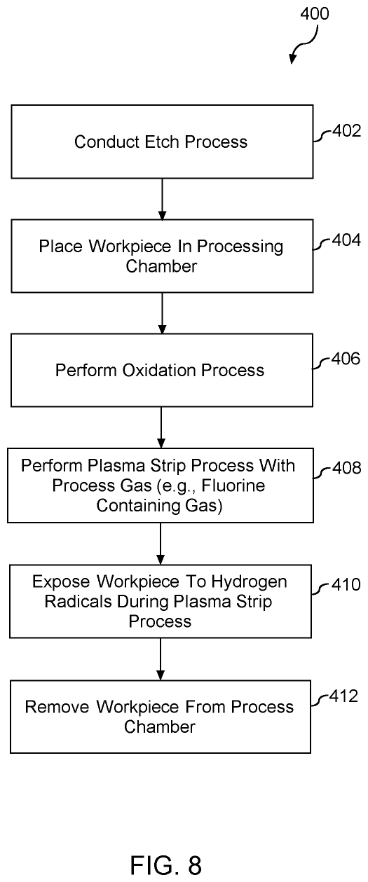

FIG. 8 depicts a flow diagram of one example method (400) according to example aspects of the present disclosure. The method (400) will be discussed with reference to the plasma processing apparatus 100 of FIG. 3 by way of example. The method (400) can be implemented in any suitable plasma processing apparatus. FIG. 8 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (402), the method can include conducting an etch process to etch a layer on a workpiece. The etch process can be carried out in a separate processing apparatus relative to the remainder of method (400) or can be conducted using the same processing apparatus. The etch process can remove at least a portion of a layer on the workpiece.

At (404), the method can include placing a workpiece in a processing chamber of a plasma processing apparatus. The processing chamber can be separated from a plasma chamber (e.g., separated by a separation grid assembly). For instance, the method can include placing a workpiece 114 onto workpiece support 112 in the processing chamber 110 of FIG. 3. The workpiece can include a BACL hardmask or other hardmask layer. The workpiece can include oxide layers and nitride layers (e.g., alternating oxide layers and nitride layers) as part of a high aspect ratio structure.

At (406), the method can include performing an oxidation process to oxidize the hardmask layer (e.g., BACL hardmask). The oxidation process can include exposing the workpiece to an oxygen containing gas and/or oxygen radicals (e.g., with or without inducing a plasma from the oxygen containing gas). The oxygen containing gas can include O₂, H₂O vapor or gas, ozone gas, N₂O, etc.). The oxygen containing gas can oxidize and remove carbonaceous material from a BACL hardmask or other hardmask layer while also oxidizing boron to boron oxide.

At (408), the method can include performing a plasma strip process, for instance, to remove a hardmask layer (e.g., BACL hardmask) from the workpiece. The plasma strip process can include, for instance, generating a plasma from a process gas in the plasma chamber 120, filtering ions with the separation grid assembly 200, and allowing neutral radicals to pass through the separation grid assembly 200. The neutral radicals can be exposed to the workpiece 114 to at least partially remove hardmask from the workpiece.

The process gas used during the plasma strip process at (408) can include a fluorine containing gas. For instance, the process gas can include HF (e.g., HF vapor). Other fluorine containing gases can be used without deviating from the scope of the present disclosure. In addition and/or in the alternative, the process gas can include a mixture of a fluorine containing gas (e.g., CF₄, NF₃, CH₂F₂, CH₃F, CFₓH_{y}, etc.) and a hydrogen containing gas (e.g., H₂, CH₄, C₂H₈, etc.).

Other suitable gases can be included in the process gas. For instance, the process gas can include an oxygen containing gas. The process gas can include a dilution gas, such as nitrogen gas N₂ and/or an inert gas, such as He, Ar or other inert gas. The process gas can include other fluorine containing gases (e.g., e.g., CF₄, NF₃, CH₂F₂, CH₃F, CFₓH_{y}, etc.).

At (410), the method can include exposing the workpiece to hydrogen radicals as a passivation agent. The hydrogen radicals can be generated by dissociating HF gas in the plasma chamber. The hydrogen radicals can be generated by dissociating a hydrogen containing gas provided as part of a process gas including a mixture of a fluorine containing gas and a hydrogen containing gas. The hydrogen radicals can improve selectivity of the strip processes for the hardmask layer relative to the nitride layers and oxide layers by acting as a passivation agent. Other suitable methods for introducing the hydrogen radicals as a passivation agent can be used without deviating from the scope of the present disclosure. As shown in FIG. 8, in some embodiments, (406), (408), and (410) can be repeated in cyclic fashion until the hardmask layer has been removed.

At (412) of FIG. 8, the method can include removing the workpiece from the processing chamber. For instance, the workpiece 114 can be removed from workpiece support 112 in the processing chamber 110. The plasma processing apparatus can then be conditioned for future processing of additional workpieces.

The plasma strip processes according to example aspects of the present disclosure can be implemented using other plasma processing apparatus without deviating from the scope of the present disclosure.

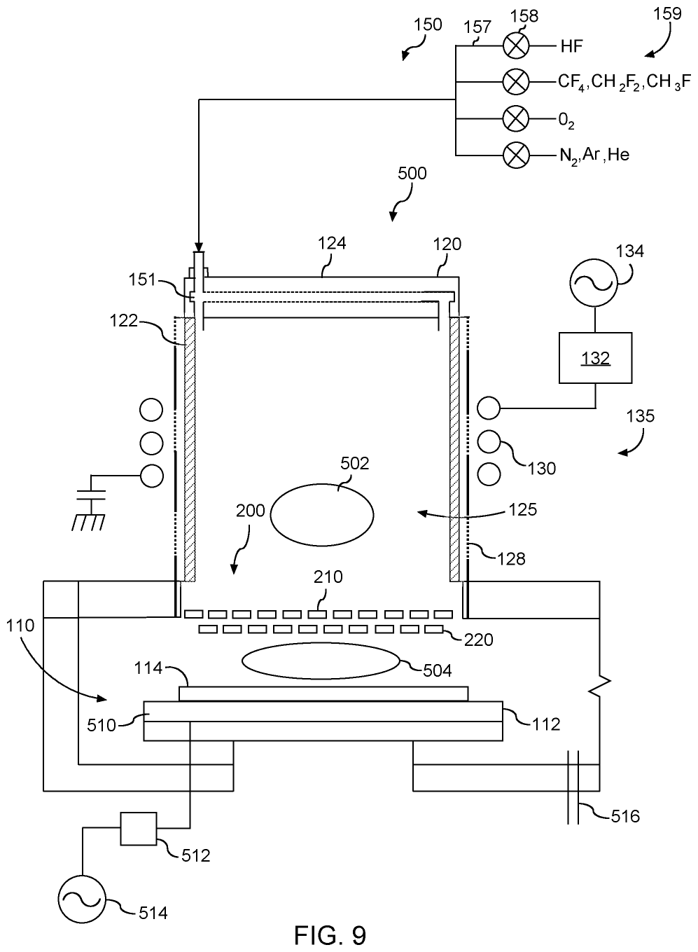

FIG. 9 depicts an example plasma processing apparatus 500 that can be used to implement processes according to example embodiments of the present disclosure. The plasma processing apparatus 500 is similar to the plasma processing apparatus 100 of FIG. 3.

More particularly, plasma processing apparatus 500 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 9, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 500 of FIG. 7 is operable to generate a first plasma 502 (e.g., a remote plasma) in the plasma chamber 120 and a second plasma 504 (e.g., a direct plasma) in the processing chamber 110. As used herein, a “remote plasma” refers to a plasma generated remotely from a workpiece, such as in a plasma chamber separated from a workpiece by a separation grid. As used herein, a “direct plasma” refers to a plasma that is directly exposed to a workpiece, such as a plasma generated in a processing chamber having a pedestal operable to support the workpiece.

More particularly, the plasma processing apparatus 500 of FIG. 7 includes a bias source having bias electrode 510 in the pedestal 112. The bias electrode 510 can be coupled to an RF power generator 514 via a suitable matching network 512. When the bias electrode 510 is energized with RF energy, a second plasma 504 can be generated from a mixture in the processing chamber 110 for direct exposure to the workpiece 114. The processing chamber 110 can include a gas exhaust port 516 for evacuating a gas from the processing chamber 110.

As shown in FIG. 9, the apparatus 100 can include a gas delivery system 150 configured to deliver process gas to the plasma chamber 120, for instance, via gas distribution channel 151 or other distribution system (e.g., showerhead). The gas delivery system can include a plurality of feed gas lines 159. The process gas can be delivered to the processing chamber 110 via the separation grid 200 acting as a showerhead.

The feed gas lines 159 can be controlled using valves and/or mass flow controllers to deliver a desired amount of gases into the plasma chamber as process gas. As shown in FIG. 9, the gas delivery system 150 can include feed gas line(s) for delivery of an HF gas (e.g., HF vapor). The gas delivery system 150 can optionally include feed gas line(s) for delivery of other gases, such as fluorine containing gas (e.g., CF₄, CH₂F₂, CH₃F). oxygen containing gas (e.g., O₂, H₂O vapor or gas, ozone gas, N₂O, etc.), a dilution gas (e.g., Na, Ar, He, or other inert gas).

According to example aspects of the present disclosure, the HF gas can be dissociated in the plasma chamber to generate hydrogen radicals and fluorine radicals. Neutral hydrogen radicals and neutral fluorine radicals can pass through the separation grid assembly 200 for exposure to the workpiece 114. The fluorine radicals can etch or remove a BACL hardmask or other hardmask layer on the workpiece 114. The hydrogen radicals can passivate oxide layers and/or nitride layers on the workpiece 114 during removal of the BACL hardmask or other hardmask layer on the workpiece 114.

In some embodiments, an oxygen containing gas can be provided to the plasma chamber and/or the processing chamber (e.g., through the separation grid assembly 200). The oxygen containing gas can be used to oxidize a hardmask layer (e.g. BACL hardmask layer) prior to removal of the hardmask layer using fluorine radicals with hydrogen radicals as a passivation agent.

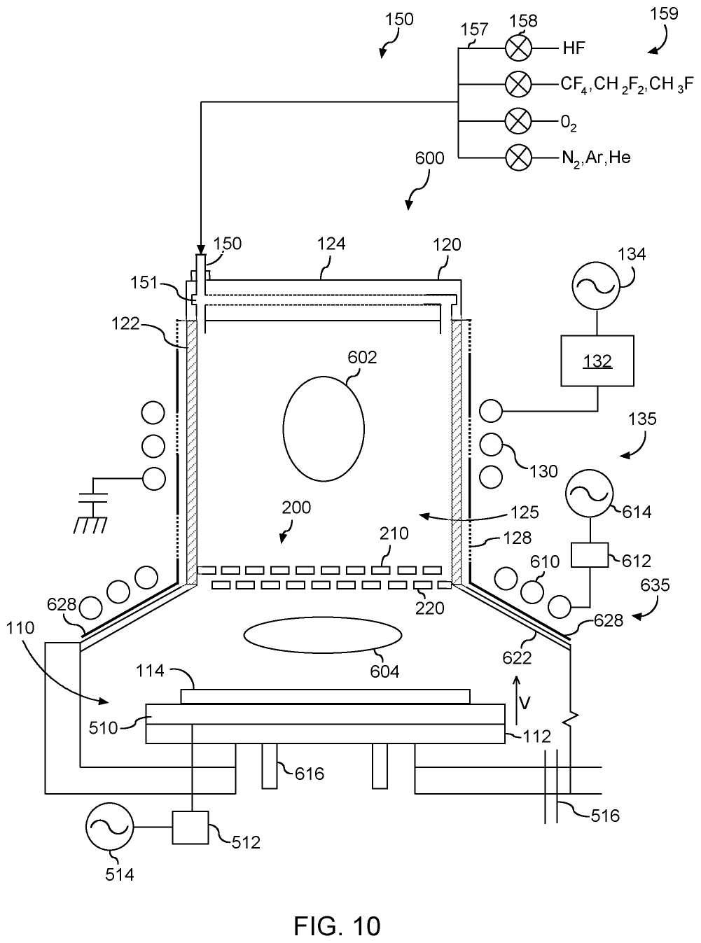

FIG. 10 depicts a processing chamber 600 similar to that of FIG. 3 and FIG. 9. More particularly, plasma processing apparatus 600 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gas (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 10, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 600 of FIG. 10 is operable to generate a first plasma 602 (e.g., a remote plasma) in the plasma chamber 120 and a second plasma 604 (e.g., a direct plasma) in the processing chamber 110. As shown, the plasma processing apparatus 600 can include an angled dielectric sidewall 622 that extends from the vertical sidewall 122 associated with the remote plasma chamber 120. The angled dielectric sidewall 622 can form a part of the processing chamber 110.

A second inductive plasma source 635 can be located proximate the dielectric sidewall 622. The second inductive plasma source 635 can include an induction coil 610 coupled to an RF generator 614 via a suitable matching network 612. The induction coil 610, when energized with RF energy, can induce a direct plasma 604 from a mixture in the processing chamber 110. A Faraday shield 628 can be disposed between the induction coil 610 and the sidewall 622.

The pedestal 112 can be movable in a vertical direction V. For instance, the pedestal 112 can include a vertical lift 616 that can be configured to adjust a distance between the pedestal 112 and the separation grid assembly 200. As one example, the pedestal 112 can be located in a first vertical position for processing using the remote plasma 602. The pedestal 112 can be in a second vertical position for processing using the direct plasma 604. The first vertical position can be closer to the separation grid assembly 200 relative to the second vertical position.

The plasma processing apparatus 600 of FIG. 10 includes a bias source having bias electrode 510 in the pedestal 112. The bias electrode 510 can be coupled to an RF power generator 514 via a suitable matching network 512. The processing chamber 110 can include a gas exhaust port 516 for evacuating a gas from the processing chamber 110.

As shown in FIG. 10, the apparatus 100 can include a gas delivery system 150 configured to deliver process gas to the plasma chamber 120, for instance, via gas distribution channel 151 or other distribution system (e.g., showerhead). The gas delivery system can include a plurality of feed gas lines 159. The process gas can be delivered to the processing chamber 110 via the separation grid 200 acting as a showerhead.

The feed gas lines 159 can be controlled using valves and/or mass flow controllers to deliver a desired amount of gases into the plasma chamber as process gas. As shown in FIG. 10, the gas delivery system 150 can include feed gas line(s) for delivery of an HF gas (e.g., HF vapor). The gas delivery system 150 can optionally include feed gas line(s) for delivery of other gases, such as fluorine containing gas (e.g., CF₄, CH₂F₂, CH₃F). oxygen containing gas (e.g., O₂, H₂O vapor or gas, ozone gas, N₂O, etc.), a dilution gas (e.g., Na, Ar, He, or other inert gas).

According to example aspects of the present disclosure, the HF gas can be dissociated in the plasma chamber to generate hydrogen radicals and fluorine radicals. Neutral hydrogen radicals and neutral fluorine radicals can pass through the separation grid assembly 200 for exposure to the workpiece 114. The fluorine radicals can etch or remove a BACL hardmask or other hardmask layer on the workpiece 114. The hydrogen radicals can passivate oxide layers and/or nitride layers on the workpiece 114 during removal of the BACL hardmask or other hardmask layer on the workpiece 114.

In some embodiments, as will be discussed in detail below, an oxygen containing gas can be provided to the plasma chamber and/or the processing chamber (e.g., through the separation grid assembly 200). The oxygen containing gas can be used to oxidize a hardmask layer (e.g. BACL hardmask layer) prior to removal of the hardmask layer using fluorine radicals with hydrogen radicals as a passivation agent.

Example process parameters for a plasma based hardmask removal process using hydrogen radicals as a passivation agent will now be set forth.

### Example 1

Process Gas: HF+O₂+H₂

Dilution Gas: Na and/or Ar and/or He

Process Pressure: about 300 mTorr to about 4000 mTorr

Inductively Coupled Plasma Source Power: about 600 W to about 5000 W

Workpiece Temperature: about 25° C. to about 400° C.

Process Period: about 30 seconds to about 1200 seconds

Total Gas Flow Rate for Process Gas: 100 sccm to 100 slm

Example process results for Example 1 are provided below:

| Parameter | Data |
|---|---|
| Pressure (mT) | 500 |
| RF Source Power (W) | 2500 |
| Temp (° C.) | 180 |
| O₂ Flow Rate (sccm) | 400 |
| N₂ Flow Rate (sccm) | 0 |
| HF (sccm) | 500 |
| H₂ (sccm) | 75 |
| Process Period (s) | 300 |
| BACL Etch Amount (Angstroms) | 7370 |
| Oxide Loss (Angstroms) | −0.45 |
| Nitride Loss (Angstroms) | 1.35 |
| BACL Etch Rate (Angstroms/minute) | 1474 |
| Oxide Selectivity relative to BACL | Infinite |
| Nitride Selectivity relative to BACL | 5459 |

Other suitable process gas mixtures are as follows: HF+O₂; HF+O₂+N₂; HF+CH₂F₂+O₂+N₂; HF+CH₃F+O₂+N₂; HF+CF₄+O₂+N₂.

Examples involving performing an oxidation process prior to the hardmask removal process are provided below:

### Example 2

Oxidation Process
Process Gas: O₂
Process Pressure: about 100 mTorr to about 5000 mTorr
Inductively Coupled Plasma Source Power: about 400 W to about 6000 W
Workpiece Temperature: about 180° C. to about 400° C.
Process Period: about 30 seconds to about 1200 seconds
Total Gas Flow Rate for Process Gas: 100 sccm to 100 slm

Removal Process
Process Gas: HF+O₂+H₂
Dilution Gas: N₂ and/or Ar and/or He
Process Pressure: about 100 mTorr to about 10000 mTorr
Inductively Coupled Plasma Source Power: about 600 W to about 5000 W
Workpiece Temperature: about 25° C. to about 400° C.
Process Period: about 30 seconds to about 1200 seconds
Total Gas Flow Rate for Process Gas: 100 sccm to 100 slm

### Example 3

Oxidation Process
Process Gas: Ozone gas
Process Pressure: about 100 mTorr to about 50000 mTorr
Ozone Concentration: about 1% to about 30% of total flow of process gas
Inductively Coupled Plasma Source Power: about 400 W to about 6000 W
Workpiece Process Temperature: about 180° C. to about 400° C.
Process Period: about 30 seconds to about 1200 seconds
Total Gas Flow Rate for Process Gas: 100 sccm to 100 slm

Removal Process
Process Gas: HF+O₂+H₂
Dilution Gas: N₂ and/or Ar and/or He
Process Pressure: about 100 mTorr to about 10000 mTorr
Inductively Coupled Plasma Source Power: about 600 W to about 5000 W
Workpiece Process Temperature: about 25° C. to about 400° C.
Process Period: about 30 seconds to about 1200 seconds
Total Gas Flow Rate for Process Gas: 100 sccm to 100 slm

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for processing a workpiece, the method comprising:
supporting a workpiece on a workpiece support in a processing chamber, the workpiece comprising a hardmask layer;
generating a plasma from a process gas in a plasma chamber using a plasma source, the process gas comprising a fluorine containing gas;
exposing the workpiece to one or more radicals generated in the plasma to perform a plasma strip process on the workpiece to at least partially remove the hardmask layer from the workpiece; and
exposing the workpiece to one or more hydrogen radicals as a passivation agent during the plasma strip process.

2. The method of claim 1, wherein the workpiece comprises one or more silicon dioxide layers and one or more silicon nitride layers.

3. The method of claim 1, wherein the plasma chamber is separated from the processing chamber by a separation grid.

4. The method of claim 1, wherein the fluorine containing gas comprises an HF gas.

5. The method of claim 1, wherein the process gas comprises a fluorine containing gas and a hydrogen containing gas.

6. The method of claim 1, wherein the process gas further comprises CF₄.

7. The method of claim 1, wherein the process gas further comprises CH₂F₂.

8. The method of claim 1, wherein the process gas further comprises CH₃F.

9. The method of claim 1, wherein the process gas comprises an oxygen gas.

10. The method of claim 1, wherein the process gas comprises a nitrogen gas.

11. The method of claim 1, wherein the hardmask is a boron doped amorphous hardmask.

12. The method of claim 1, wherein the plasma strip process is implemented for a process period, the process period being in a range of about 30 seconds to about 1200 seconds.

13. The method of claim 1, wherein the plasma strip process is conducted at a process pressure in the processing chamber, the process pressure being in a range of about 300 mT to about 4000 mT.

14. The method of claim 1, wherein the plasma strip is conducted at a source power for an inductively coupled plasma source, the source power being in the range of about 600 W to about 5000 W.

15. The method of claim 1, wherein the plasma strip process is conducted with the workpiece at a process temperature, the process temperature being in a range of about 25° C. to about 400° C.

16. The method of claim 1, wherein exposing the workpiece to one or more hydrogen radicals as a passivation agent comprises introducing HF gas into the processing chamber.

17. The method of claim 19, wherein exposing the workpiece to one or more hydrogen radicals as a passivation agent comprises introducing HF gas into the processing chamber at a location beneath a separation grid.

18. The method of claim 19, wherein exposing the workpiece to one or more hydrogen radicals as a passivation agent comprises introducing HF gas at a location between a first grid plate and a second grid plate of a separation grid.

19. The method of claim 1, wherein prior to generating a plasma from a process gas in a plasma chamber using a plasma source, the process gas comprising a fluorine containing gas; and exposing the workpiece to one or more radicals generated in the plasma to perform a plasma strip process, the method comprises performing an oxidation process on the workpiece.

20. The method of claim 19, wherein the oxidation process comprises:
exposing the workpiece to an oxygen containing gas.
